(19) United States
(12) Patent Application Publication
(10) Pub. No.: US 2026/0155819 A1
(43) Pub. Date: Jun. 4, 2026

(54) SWITCH DRIVER, BATTERY MANAGEMENT SYSTEM, AND BATTERY PACK

(71) Applicant: Samsung SDI Co., Ltd., Yongin-si (KR)

(72) Inventors: Kyo Song Koo, Suwon-si (KR); Peter Kurcik, Suwon-si (KR); Matthias Flatscher, Suwon-si (KR); Kwang Min Yoo, Suwon-si (KR); Hyun Kim, Suwon-si (KR)

(73) Assignee: Samsung SDI Co., Ltd., Yongin-si (KR)

(21) Appl. No.: 19/319,113

(22) Filed: Sep. 4, 2025

(30) Foreign Application Priority Data
Dec. 4, 2024 (KR) 10-2024-0178278

(51) Int. Cl. H03K 17/22; H02J 7/00; H03K 3/356; H03K 17/16

(52) U.S. Cl. CPC H03K 17/223; H02J 7/933; H03K 3/356008; H03K 17/162; H02J 2105/37; H03K 2217/0063; H03K 2217/0072

(57) ABSTRACT

The present disclosure relates to a switch driver, a battery management system, and a battery pack, and a technical object to be solved is to provide a circuit topology capable of improving the operational reliability and operational stability of a main switch provided in a battery pack. To this end, the present disclosure adopts a signal duplication topology in which a disable signal for an operation of turning off a main switch is added as a control signal of the main switch in addition to an enable signal for an operation of turning on the main switch, and a driver duplication topology in which a sub-driver operating as a latch circuit that maintains an operating state of the main driver for driving the main switch is added.

### CROSS-REFERENCE TO RELATED APPLICATIONS

This present application claims priority to and the benefit under 35 U.S.C. § 119(a)-(d) of Korean Patent Application No. 10-2024-0178278, filed on Dec. 4, 2024, in the Korean Intellectual Property Office, the entire disclosure of which is incorporated herein by reference.

### FIELD

The present disclosure relates to a switch driver for driving a control target switch, a battery management system including the same, and a battery pack.

### BACKGROUND

A battery pack includes battery cells and a peripheral circuit including a charge/discharge circuit. The peripheral circuit is manufactured as a printed circuit board and then connected to the battery cells. When an external power source is connected to external terminals of the battery pack, the battery cells are charged, and when a load is connected to the external terminals, the battery cells are discharged. The charge/discharge circuit controls the charging/discharging of the battery cells between the external terminals and the battery cells. In general, a plurality of battery cells are connected in series and in parallel according to the consumption capacity of a load. A main switch such as a relay or a contactor is provided in a battery pack to allow or block the electrical connection of battery cells to an external power source or load, and a driver (for example, a relay driver implemented as a high-side switch (HSS) or a low-side switch (LSS)) is provided in the battery pack to drive the main switch.

The above information disclosed in this Background section is for enhancement of understanding of the background of the present disclosure, and therefore, it may contain information that does not constitute related (or prior) art.

### SUMMARY

The present disclosure is directed to providing a switch driver capable of improving the operational reliability and operational stability of a main switch provided in a battery pack, a battery management system, and a battery pack.

However, objects that the present disclosure intends to achieve are not limited to the herein-described objects and other objects that are not described may be clearly understood by those skilled in the art from the following description.

According to aspects of the present disclosure, there is provided a switch driver including a first switch turned on or off according to a state of an enable signal input through a first input node to perform an operation of turning on a control target switch, a second switch turned on or off according to a state of a disable signal input through a second input node to perform an operation of turning off the control target switch and connected an output node at which a driving signal for driving turning-on or turning-off of the control target switch is generated, a third switch turned on or off in a complementary manner to the second switch, and a fourth switch connected between the output node and a power node to which a power voltage for generating the driving signal is input and configured to drive a flow of a current for generating the driving signal, wherein the first to fourth switches operate as a latch circuit configured to maintain a current state of the driving signal when a predefined latch condition is satisfied according to the state of the enable signal and the state of the disable signal.

The latch condition may be a condition in which the state of the enable signal transitions while the disable signal remains in a same state.

The switch driver may further include a connection circuit configured to connect the first to fourth switches to operate the first to fourth switches as the latch circuit when the latch condition is satisfied.

Each of the first to fourth switches may be implemented as a transistor including a control terminal to which a control signal for determining turning-on or turning-off of each switch is input, and a current supply terminal and a current discharge terminal which are electrically connected to one another and allow a current to flow when each switch is turned on.

The current supply terminal of the first switch, the current supply terminal of the third switch, the control terminal of the fourth switch, and the power node may be connected in common through the connection circuit.

The current supply terminal of the second switch, the control terminal of the third switch, and the current discharge terminal of the fourth switch may be connected to the output node through the connection circuit, and the current discharge terminal of the second switch may be connected to a ground node.

The connection circuit may include an output resistor connected between the output node and the ground node to form the state of the driving signal to be at a high level.

In a first input condition in which the state of the enable signal and the state of the disable signal are at a high level and a low level, respectively, the fourth switch may be turned on by a branch current branching off from a current generated when the first switch is turned on, and the state of the driving signal may be formed at a high level by the output resistor and a current flowing through the fourth switch as the fourth switch is turned on.

When the first input condition transitions to a second state in which the state of the enable signal is at a low level, as a turned-on state of the fourth switch is maintained, the state of the driving signal may be maintained at a high level by the output resistor and the current flowing through the fourth switch.

The first input condition may transition to the second input condition independently of an operation of a processor configured to apply the enable signal and the disable signal to the first and second switches, respectively.

Under a third input condition in which the state of the enable signal and the state of the disable signal are at a low level and a high level, respectively, as the second switch is turned on and the output node is connected to the ground node, the state of the driving signal may be formed at a low level.

When the third input condition transitions to a fourth input condition in which the state of the enable signal is at a high level, as a turned-on state of the second switch is maintained, the state of the driving signal may be maintained at a low level.

The third input condition may transition to the fourth input condition independently of an operation of a processor configured to apply the enable signal and the disable signal to the first and second switches, respectively.

The control target switch may include a high-side switch (HSS) or a low-side switch (LSS) which is turned on or off by the driving signal to drive the main switch.

According to aspects of the present disclosure, there is provided a battery management system including a main switch configured to allow or block power supply to a load, a main driver including a driving switch configured to drive the main switch, a sub-driver configured to apply a driving signal to the main driver through a plurality of switches to drive the driving switch of the main driver, and a processor configured to control an operation of the sub-driver by respectively applying an enable signal and a disable signal to a first switch and a second switch among the plurality of switches included in the sub-driver, wherein the enable signal is a signal for an operation of turning on the driving switch, and the disable signal is a signal for an operation of turning off the driving switch, wherein the sub-driver operates as a latch circuit configured to maintain a current state of the driving signal when a predefined latch condition is satisfied according to a state of the enable signal and a state of the disable signal.

The sub-driver may include a first switch turned on or off according to the state of the enable signal, a second switch turned on or off according to the state of the disable signal and connected to an output node at which the driving signal is generated, a third switch turned on or off in a complementary manner to the second switch, and a fourth switch connected between the output node and a power node to which a power voltage for generating the driving signal is input and configured to drive a flow of a current for generating the driving signal.

The latch condition may be a condition in which the state of the enable signal transitions while the disable signal remains in a same state.

The main switch may include a relay including a relay coil and a contact switch configured to perform a contact switching operation according to whether the relay coil is electrically connected.

The driving switch may include an HSS or an LSS which controls whether to electrically connect the relay coil.

According to aspects of the present disclosure, there is provided a battery pack including a main switch configured to allow or block an electrical connection between a first battery and a load, a main driver including a driving switch configured to drive the main switch by being turned on or off according to whether an electrical connection is made with the second battery, a sub-driver configured to apply a driving signal to the main driver through a plurality of switches to drive the driving switch of the main driver, and a processor configured to control an operation of the sub-driver by respectively applying an enable signal and a disable signal to a first switch and a second switch among the plurality of switches included in the sub-driver, wherein the enable signal is a signal for an operation of turning on the driving switch, and the disable signal is a signal for an operation of turning off the driving switch, wherein the sub-driver is configured to drive the driving switch by prioritizing the disable signal when the enable signal and the disable signal are at a mutually incompatible state.

When the state of the enable signal and the state of the disable signal both are at a high level, the sub-driver may be configured to form the state of the driving signal to be at a low level and apply the driving signal to the main driver, and when the state of the driving signal is formed at a low level, the driving switch and the main switch may provide a turning-off operation to cut off the electrical connection between the first battery and the load.

According to aspects of the present disclosure, there is provided a method of operating battery pack including: with a main switch, allowing or blocking an electrical connection between a first battery and a load; with a main driver including a driving switch, driving the main switch to be turned on or off according to whether an electrical connection is made with the second battery; with a sub-driver, applying a driving signal to the main driver through a plurality of switches to drive the driving switch of the main driver; and with a processor, controlling an operation of the sub-driver by respectively applying an enable signal and a disable signal to a first switch and a second switch among the plurality of switches included in the sub-driver, wherein the enable signal is a signal for an operation of turning on the driving switch, and the disable signal is a signal for an operation of turning off the driving switch, wherein the sub-driver is configured to drive the driving switch by prioritizing the disable signal when the enable signal and the disable signal are at a mutually incompatible state.

### BRIEF DESCRIPTION OF THE DRAWINGS

The following drawings attached to this specification illustrate embodiments of the present disclosure, and further describe aspects and features of the present disclosure together with the detailed description of the present disclosure. Thus, the present disclosure should not be construed as being limited to the drawings:

FIG. 1 is a block diagram of a battery pack to which a sub-driver may be applied according to embodiments of the present disclosure;

FIGS. 2 and 3 are circuit diagrams of a main driver and a main switch driven by the sub-driver according to embodiments of the present disclosure;

FIG. 4 is a block diagram of a battery pack according to embodiments of the present disclosure;

FIG. 5 illustrates an example of a main driver being driven by a sub-driver according to embodiments of the present disclosure;

FIG. 6 illustrates a circuit diagram of the sub-driver according to embodiments of the present disclosure; and

FIGS. 7 to 10 are exemplary diagrams illustrating an operation method of the sub-driver according to embodiments of the present disclosure.

### DETAILED DESCRIPTION

Hereinafter, embodiments of the present disclosure will be described, in detail, with reference to the accompanying drawings. The terms or words used in this specification and claims should not be construed as being limited to the usual or dictionary meaning and should be interpreted as meaning and concept consistent with the technical idea of the present disclosure based on the principle that the inventor can be his/her own lexicographer to appropriately define the concept of the term to explain his/her disclosure in the best way.

The embodiments described in this specification and the configurations shown in the drawings are only some of the embodiments of the present disclosure and do not represent all of the technical ideas, aspects, and features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. When phrases such as “at least one of A, B and C, “at least one of A, B or C,” “at least one selected from a group of A, B and C,” or “at least one selected from among A, B and C” are used to designate a list of elements A, B and C, the phrase may refer to any and all suitable combinations or a subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed herein could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

References to two compared elements, features, etc. as being “the same” may mean that they are “substantially the same”. Thus, the phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

When an arbitrary element is referred to as being disposed (or located or positioned) on the “above (or below)” or “on (or under)” a component, it may mean that the arbitrary element is placed in contact with the upper (or lower) surface of the component and may also mean that another component may be interposed between the component and any arbitrary element disposed (or located or positioned) on (or under) the component.

In addition, it will be understood that when an element is referred to as being “coupled,” “linked” or “connected” to another element, the elements may be directly “coupled,” “linked” or “connected” to one another, or an intervening element may be present therebetween, through which the element may be “coupled,” “linked” or “connected” to another element. In addition, when a part is referred to as being “electrically coupled” to another part, the part can be directly connected to another part or an intervening part may be present therebetween such that the part and another part are indirectly connected to one another.

Throughout the specification, when “A and/or B” is stated, it means A, B or A and B, unless otherwise stated. That is, “and/or” includes any or all combinations of a plurality of items enumerated. When “C to D” is stated, it means C or more and D or less, unless otherwise specified. 1.

1. Battery Pack to which Sub-Driver is Applied

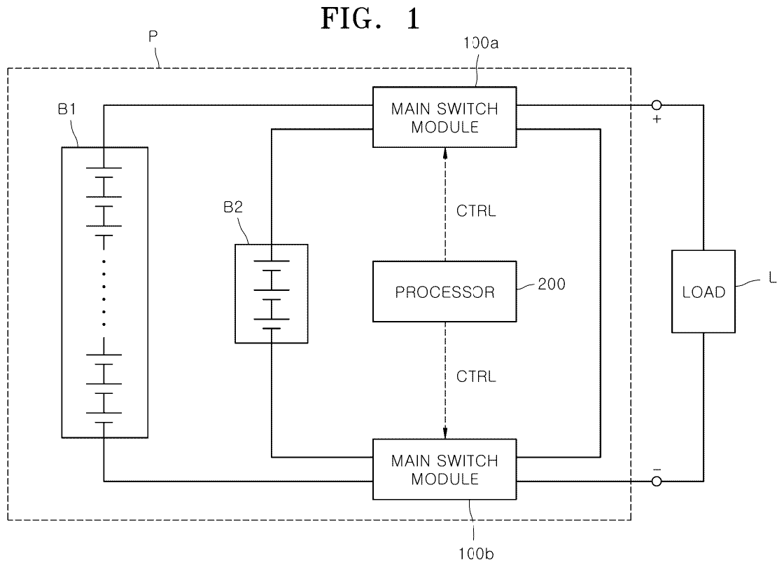

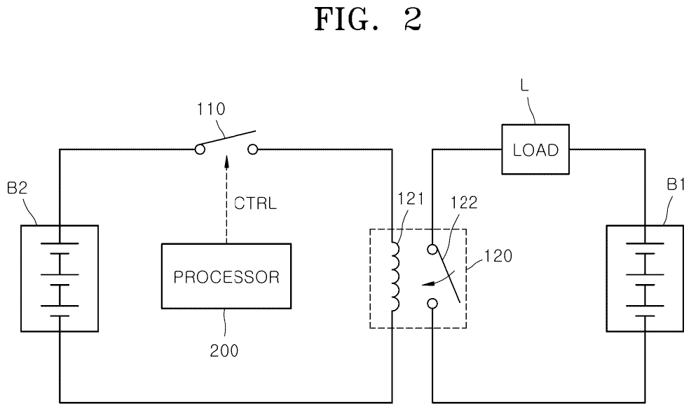

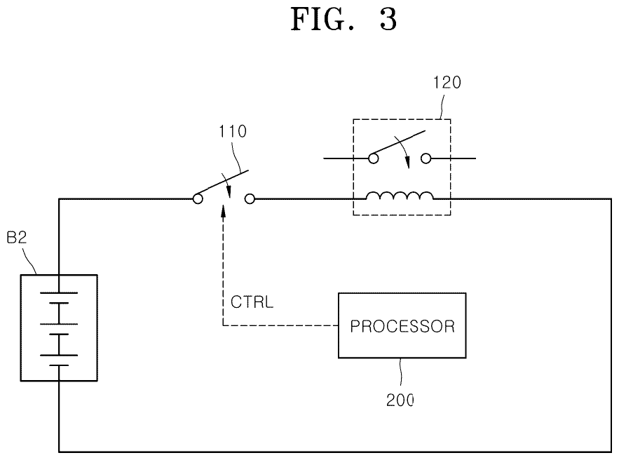

FIG. 1 is a block diagram of a battery pack to which a sub-driver may be applied according to embodiments of the present disclosure. FIGS. 2 and 3 are circuit diagrams of a main driver and a main switch driven by the sub-driver according to embodiments of the present disclosure. A battery pack P, a main driver 110, and a main switch 120 of FIGS. 1 to 3 serve as components constituting embodiments.

The battery pack P of FIG. 1 may include a first battery B1, a second battery B2, the main driver 110, the main switch 120, and a processor 200, and the main driver 110, the main switch 120, and the processor 200 included in the battery pack P may serve as components constituting a battery management system. FIG. 1 illustrates a structure in which by defining a component including the main driver 110 and the main switch 120 as a main switch module 100, main switch modules 100a and 100b are provided at a positive terminal and a negative terminal of the first battery B1, respectively.

Describing each component in detail, the first battery B1 may correspond to a battery module in which a plurality of battery cells are connected in series (which includes a structure in which a plurality of battery modules are connected in series). When the battery pack P is applied to an electric vehicle, the first battery B1 may be implemented as a high-voltage battery (for example, a lithium ion battery, a lithium polymer battery, a nickel cadmium battery, a nickel hydrogen battery, or a nickel zinc battery) that supplies a high voltage (for example, 400 V or 800 V). The first battery B1 may be a main battery that supplies power to a load, that is, a driving system of an electric vehicle (for example, a driving motor and an inverter), to drive the driving system or may be charged by a charging current supplied from an external charging device.

The second battery B2 may also correspond to a battery module in which a plurality of battery cells are connected in series (which includes a structure in which a plurality of battery modules are connected in series). When the battery pack P is applied to an electric vehicle, the second battery B2 may be implemented as a low-voltage battery (for example, a lead-acid battery) that supplies a low voltage (for example, 12 V). The second battery B2 may be an auxiliary battery that supplies power to an electrical system of an electric vehicle (for example, a lamp system, a wiper system, or an air conditioning system). As described herein, the driving switch 110 may be configured to turn the main switch 120 on by being turned on in a state of being electrically connected to the second battery B2.

The main switch 120 may be configured to allow or block an electrical connection between the first battery B1 and a load L (for example, a driving motor of an electric vehicle) and may be implemented as various types of switching elements such as a relay or a metal oxide silicon field effect transistor (MOSFET). The main driver 110 may include the driving switch 110 that drives the main switch 120, and the driving switch 110 may also be implemented as various types of switch elements such as a relay or a MOSFET.

In embodiments shown in FIG. 2, the main switch 120 may be implemented as a relay including a relay coil 121 and a contact switch 122 that performs a contact switching operation according to whether the relay coil 121 is electrically connected. The driving switch 110 that drives the main switch 120 may be implemented as a high-side switch (HSS) or a low-side switch (LSS) that controls whether to electrically connect the relay coil 121 of the main switch 120 (that is, whether to electrically connect the relay coil 121 and the second battery B2 to one another) (in order to help understand embodiments, in embodiments, an example in which that the driving switch 110 is a high-side switch is described). When the driving switch 110 is turned off, the relay coil 121 and the second battery B2 may be electrically disconnected from one another, and thus the main switch 120 may remain in a turned-off state (that is, an open state of the contact switch 122). When the driving switch 110 is turned on, the relay coil 121 may be connected to the second battery B2 and magnetized so that the main switch 120 may remain in a turned-on state (that is, a closed state of the contact switch 122).

The processor 200 may be implemented as an analog front end integrated circuit (AFE IC) or a microcontroller unit (MCU) of the battery management system provided in the battery pack P. Accordingly, during the operation of the battery pack P, the processor 200 may monitor a state of the first battery B1 and may perform a battery cell control operation according to monitoring results. For example, the processor 200 may be configured to monitor a voltage, a current, a temperature, and a state of charge (SoC) of the first battery B1 and may perform control operations such as balancing control, temperature control, and charge/discharge control operations of the first battery B1 based on monitoring results or perform protection operations of preventing over-discharging or over-charging, such as a switch control operation.

In general, the processor 200 is configured to drive the driving switch 110 to control an operation of turning the main switch 120 on or off. Referring to FIG. 3, the processor 200 controls the operations of the driving switch 110 and the main switch 120 by applying a main switch control signal CTRL to the driving switch 110. For example, when the processor 200 applies the main switch control signal CTRL at a high level to the driving switch 110, the driving switch 110 may be turned on, and the relay coil 121 of the main switch 120 may be connected to the second battery B2 and magnetized so that the main switch 120 may be turned on. When the processor 200 applies the main switch control signal CTRL at a low level to the driving switch 110 (which has the same meaning as stopping a state in which the main switch control signal CTRL at a high level is applied to the driving switch 110), the driving switch 110 may turned off, and the relay coil 121 of the main switch 120 and the second battery B2 may be electrically disconnected from one another so that the main switch 120 may be turned off.

According to such a main switch control method, there is a problem in that an unintended malfunction of the main switch 120 is caused when noise is included in the main switch control signal CTRL for controlling the operation of the main switch 120. For example, in a state in which the main switch control signal CTRL at a low level is applied to the main driver 110, when noise acts on the main switch control signal CTRL to change a level of the main switch control signal CTRL into that of a high level (which means a level change due to noise irrespective of the control of the processor 200), the main switch 120 may be switched from a turned-off state to a turned-on state, which may cause an abnormal power supply operation of the battery pack P. Assuming that the battery pack P is applied to an electric vehicle, in a state in which power is not supplied from the battery pack P to a driving motor (that is, in a non-driving state), when noise acts on the main switch control signal CTRL to change a level of the main switch control signal CTRL into that of a high level, the vehicle may abnormally operate due to sudden driving of the driving motor, which may cause an accident.

In order to solve the problems described herein, in embodiments, the main switch control signal CTRL for controlling the main switch 120 is duplicated into an enable signal and a disable signal, and a latch circuit capable of processing a duplicated control signal is added to the battery pack P to focus on securing the operational reliability and operational stability of the main switch 120, and a detailed description thereof is provided herein.

2. Battery Pack to which Sub-Driver is Applied, and Sub-Driver

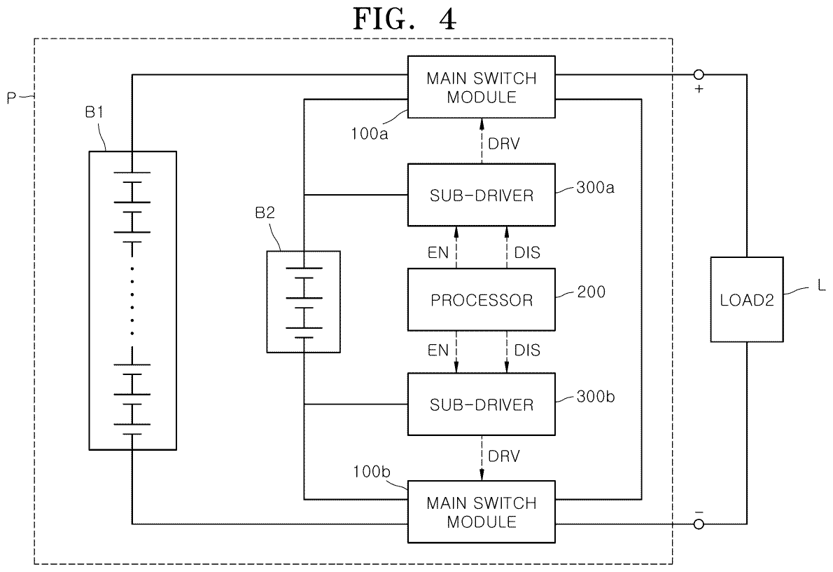

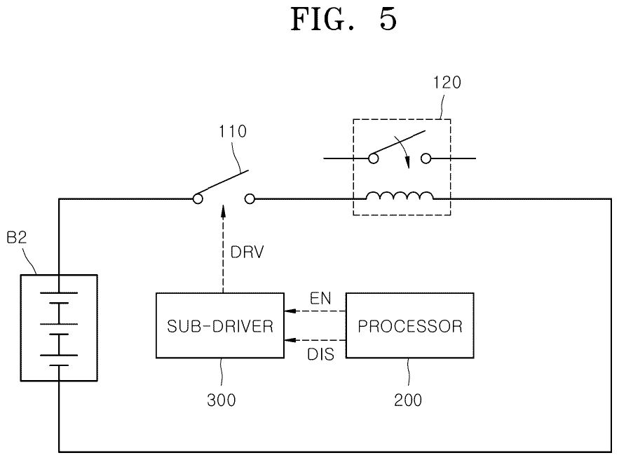

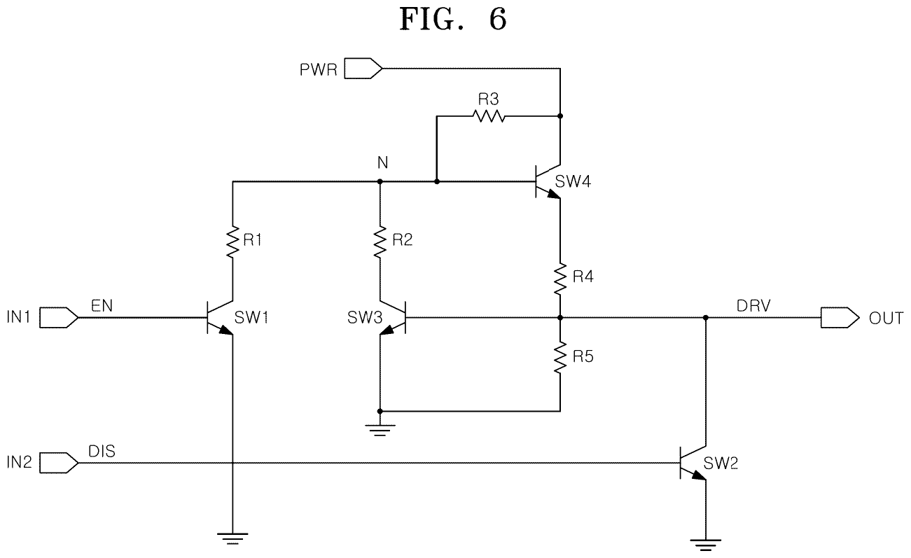

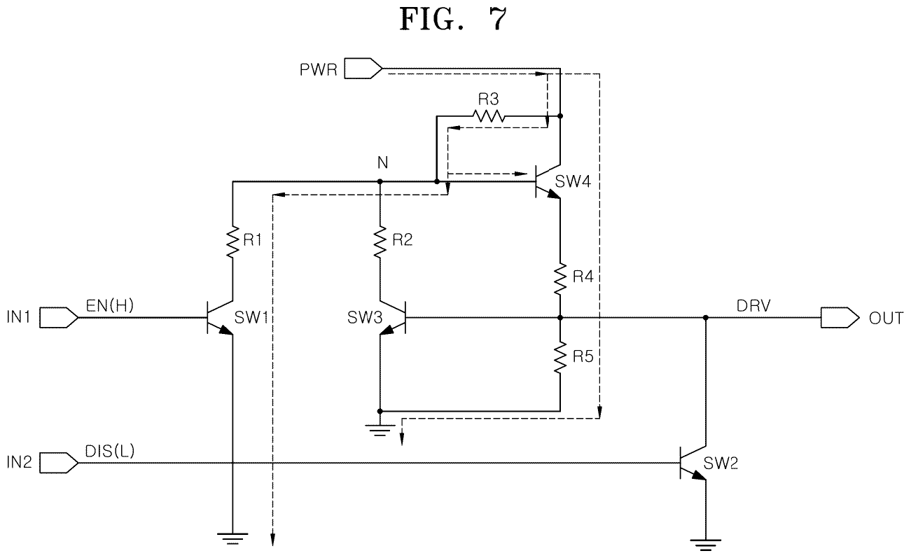

FIG. 4 is a block diagram of a battery pack according to embodiments of the present disclosure. FIG. 5 is an exemplary diagram illustrating an example of a main driver 110 being driven by a sub-driver according to embodiments of the present disclosure. FIG. 6 is a circuit diagram of the sub-driver according to embodiments of the present disclosure. FIGS. 7 to 10 are exemplary diagrams illustrating an operation method of the sub-driver according to embodiments of the present disclosure.

Prior to providing a specific description of the embodiments, first, when terms used herein are clearly defined, the terms “control target switch” (see the claims) and “driving switch” refer to the same component, and the terms “switch driver” (see the claims) and “sub-driver” refer to the same component. In order to unify the terms, hereinafter, the terms “driving switch” and “sub-driver” are used to describe embodiments.

FIG. 4 illustrates a battery pack P to which a sub-driver 300 focused on in embodiments is added in comparison to that of FIG. 1. In FIG. 4, the main driver 110, the sub-driver 300, a main switch 120, and a processor 200 may constitute a battery management system. FIG. 4 illustrates a structure in which by defining a component including the main driver 110 and the main switch 120 as a main switch module 100, main switch modules 100a and 100b are provided at a positive terminal and a negative terminal of a first battery B1, respectively. In addition, FIG. 4 illustrates a structure in which two sub-drivers 300a and 300b are provided to drive the main switch modules 100a and 100b, and the sub-drivers 300a and 300b have the same operation.

The processor 200 may be configured to control the operation of the sub-driver 300 by respectively applying an enable signal and a disable signal to first and second switches SW1 and SW2 (described herein) among a plurality of switches included in the sub-driver 300. Here, an enable signal EN is a signal for an operation of turning the driving switch 110 on, and a disable signal DIS is a signal for an operation of turning the driving switch 110 off. That is, the processor 200 may be configured to apply the enable signal EN at a high level and the disable signal DIS at a low level to the sub-driver 300 when turning on the main switch 120 and may be configured to apply the enable signal EN at a low level and the disable signal DIS at a high level to the sub-driver 300 when turning off the main switch 120.

Assuming that there is no noise, when the enable signal EN at a high level is applied from the processor 200 to the sub-driver 300, a driving signal DRV at a high level (a signal for driving the driving switch 110) (described herein) is applied from the sub-driver 300 so that the driving switch 110 is turned on, and a relay coil 121 of the main switch 120 is connected to the second battery B2 and magnetized so that the main switch 120 is turned on. When the disable signal DIS at a high level is applied from the processor 200 to the sub-driver 300, the driving switch 110 is turned off, and the relay coil 121 of the main switch 120 and a second battery B2 are electrically disconnected from one another so that the main switch 120 is turned off (see FIG. 5). Accordingly, there may be provided a circuit topology in which a control signal for controlling the main switch 120 is duplicated into the enable signal EN and the disable signal DIS, and also in which a driver for driving the main switch 120 is duplicated into the main driver 110 and the sub-driver 300.

In order to prevent a situation in which the main switch 120 malfunctions as noise acts on the enable signal EN or the disable signal DIS to change a level thereof, it is required that the processor 200 has a latch circuit to maintain a state of the driving signal DRV applied to the driving switch 110 even when an unintended change of the enable signal EN or disable signal DIS occurs, and the latch circuit is implemented by the sub-driver 300.

Referring to FIG. 6, the sub-driver 300 of embodiments may include first to fourth switches SW1 to SW4 and a connection circuit. The sub-driver 300 may have first and second input nodes IN1 and IN2 as nodes for receiving the enable signal EN and the disable signal DIS from the processor 200, a power node PWR as a node for receiving a power voltage from the second battery B2, and an output node OUT as a node for outputting a driving signal (hereinafter abbreviated as the driving signal DRV) for driving the turning-on or turning-off of the driving switch 110.

Each of the first to fourth switches SW1 to SW4 may be implemented as a transistor including a control terminal to which a control signal for determining the turning-on or turning-off of each switch is input, and a current supply terminal and a current discharge terminal that are electrically connected to one another when each switch is turned on and allow a current to flow. In an example in which the first to fourth switches SW1 to SW4 are implemented as bipolar junction transistors (BJTs) (NPN), the herein-described control terminal, current supply terminal, and current discharge terminal may be a base terminal, a collector terminal, and an emitter terminal, respectively. In an example in which the first to fourth switches SW1 to SW4 are implemented as field effect transistors (FETs) (N-type), the herein-described control terminal, current supply terminal, and current discharge terminal may be a gate terminal, a drain terminal, and a source terminal, respectively (it is obvious that the definitions of the current supply terminal and the current discharge terminal also change when the types of BJT and FET are switched). In embodiments, an example in which the first to fourth switches SW1 to SW4 are implemented as BJTs (NPN) is described. Accordingly, the first to fourth switches SW1 to SW4 may be turned on when a high-level signal is input and may be turned off when a low-level signal is input through each control terminal.

The connection circuit may include first to fifth resistors R1 to R5 for connecting the first to fourth switches SW1 to SW4 (the connection circuit may also be defined as including wires for connecting respective terminals between the first to fourth switches SW1 to SW4). Resistance values of the first to fifth resistors R1 to R5 may be designed based on experimental results of a designer on the operation of the sub-driver 300 for generating the driving signal DRV at a high level or low level at the output node OUT. In particular, as shown in FIG. 6, the fifth resistor R5 may be connected between the output node OUT and a ground node and may serve as an output resistor for forming a state of the driving signal DRV to be at a high level (for example, a power voltage of the second battery B2).

A circuit connection structure of the sub-driver 300 is described in detail.

The first switch SW1 may be turned on or off according to a state of the enable signal EN input through the first input node IN1, and the first input node IN1 may be connected to the control terminal of the first switch SW1. The current supply terminal of the first switch SW1 may be connected to an intermediate node N through the first resistor R1 of the connection circuit, and the current discharge terminal of the first switch SW1 may be connected to the ground node.

The second switch SW2 may be turned on or off according to a state of the disable signal DIS input through the second input node IN2, and the second input node IN2 may be connected to the control terminal of the second switch SW2. The current supply terminal of the second switch SW2 may be connected to the output node OUT, and the current discharge terminal of the second switch SW2 may be connected to the ground node.

The third switch SW3 may be turned on or off according to a state of the driving signal DRV generated at the output node OUT, and the output node OUT may be connected to the control terminal of the third switch SW3. When the second switch SW2 is turned on, the output node OUT may be connected to the ground node so that the third switch SW3 may be turned off, and when the second switch SW2 is turned off, a high-level potential may be generated at the output node OUT by the output resistor R5 (described herein) so that the third switch SW3 may be turned on. That is, the second switch SW2 and the third switch SW3 may be turned on or off in a complementary manner. The current supply terminal of the third switch SW3 may be connected to the intermediate node N through the second resistor R2 of the connection circuit, and the current discharge terminal of the third switch SW3 may be connected to the ground node.

The fourth switch SW4 is connected between the power node PWR, to which a power voltage (for example, a power voltage of the second battery B2) for generating the driving signal DRV is input, and the output node OUT and may operate to drive a flow of a current for generating the driving signal DRV. The control terminal of the fourth switch SW4 may be connected to the intermediate node N, the current supply node of the fourth switch SW4 may be connected to the power node PWR and at the same time may be connected to the intermediate node N through the third resistor R3 of the connection circuit, and the current discharge node of the fourth switch SW4 may be connected to the output node OUT through the fourth resistor R4 of the connection circuit.

When the driving switch 110 is controlled through the sub-driver 300, and thus the main switch 120 is normally controlled, the processor 200 may be configured to apply the enable signal EN at a high level and the disable signal DIS at a low level to the sub-driver 300 when turning the main switch 120 on and may be configured apply the enable signal EN at a low level and the disable signal DIS at a low level to the sub-driver 300 when turning the main switch 120 off. That is, the processor 200 may be configured to apply the enable signal EN and the disable signal DIS having complementary states to the sub-driver 300 when controlling the main switch 120.

Specifically, when the main switch 120 is turned on, the processor 200 may respectively apply the enable signal EN at a high level and the disable signal DIS at a low level to the first input node IN1 and the second input node IN2 of the sub-driver 300 so that the first switch SW1 is turned on and the second switch SW2 is turned off.

As the first switch SW1 is turned on, a current path along which the power node PWR, the third resistor R3, the first resistor R1, the first switch SW1, and the ground node are connected is formed, and a current flows from the power node PWR to the ground node through the formed current path.

The flowing current branches off from the intermediate node N so that a branch current that flows toward the control terminal of the fourth switch SW4 is generated, and the fourth switch SW4 is turned on by the generated branch current.

As the fourth switch SW4 is turned on, a constant voltage (power voltage of the second battery B2) is generated at the output node OUT by a current flowing through the fourth switch SW4 and the output resistor R5 connected between the output node OUT and the ground node, and thus a state of the driving signal DRV of the output node OUT is formed at a high level. As the driving signal DRV at a high level is generated at the output node OUT, the driving switch 110 and the main switch 120 may be turned on.

When the main switch 120 is turned off, the processor 200 may respectively apply the enable signal EN at a low level and the disable signal DIS at a high level to the first input node IN1 and the second input node IN2 of the sub-driver 300 so that the first switch SW1 is turned off, and the second switch SW2 is turned on. By the turning-on operation of the second switch SW2, the output node OUT is connected to the ground node, and a state of the driving signal DRV of the output node OUT is formed at a low level (the third switch SW3 having the output node OUT as the control terminal is also turned off). As the driving signal DRV at a low level is generated at the output node OUT, the driving switch 110 and the main switch 120 may be turned off.

Through such a process, the processor 200 may control the turning-on and turning-off operations of the main switch 120, and in this case, when noise acts on the enable signal EN or the disable signal DIS as described herein, an unintended state change (level change) of the enable signal EN or the disable signal DIS may occur. The sub-driver 300 of embodiments has a circuit configuration that is robust with respect to an unintended state change of the enable signal EN or the disable signal DIS through an operation of latching onto a state of the driving signal DRV generated at the output node OUT. To this end, the first to fourth switches SW1 to SW4 of the sub-driver 300 may operate as a latch circuit that maintains a current state of the driving signal DRV when a predefined latch condition is satisfied according to a state of the enable signal EN and a state of the disable signal DIS. The herein-described latch condition may be a condition in which a state of the enable signal EN transitions while the disable signal DIS remains in the same state.

A method in which the sub-driver 300 operates as a latch circuit that maintains a current state of the driving signal DRV is described based on a state in which each state of the enable signal EN and the disable signal DIS is formed as shown in Table 1 below. The operation of the sub-driver 300 to be described herein is an operation in which each state of the enable signal EN and the disable signal DIS sequentially transitions from a first input condition to a fourth input condition. Since a condition in which the state of the enable signal EN transitions while the disable signal DIS remains in the same state is defined as a latch condition, embodiments focuses on a case in which the first input condition transitions to a second input condition and a case in which a third input condition transitions to the fourth input condition, as provided in Table 1.

TABLE 1

| Input condition | Enable signal | Disable signal | Driving signal |
|---|---|---|---|
| First input condition | High | Low | High |
| Second input condition | Low | Low | High |
| Third input condition | Low | High | Low |
| Fourth input condition | High | High | Low |

Referring to FIG. 7, under the first input condition in which the enable signal EN at a high level and the disable signal DIS at a low level are input from the processor 200 to the first input node IN1 and the second input node IN2 of the sub-driver 300, respectively, the first switch SW1 is turned on, and the second switch SW2 is turned off.

As the first switch SW1 is turned on, a current path along which the power node PWR, the third resistor R3, the first resistor R1, the first switch SW1, and the ground node are connected is formed, and a current flows from the power node PWR to the ground node through the formed current path.

The flowing current branches off from the intermediate node N so that a branch current that flows toward the control terminal of the fourth switch SW4 is generated, and the fourth switch SW4 is turned on by the generated branch current.

As the fourth switch SW4 is turned on, a constant voltage (power voltage of the second battery B2) is generated at the output node OUT by a current flowing through the fourth switch SW4 and the output resistor R5 connected between the output node OUT and the ground node, and thus a state of the driving signal DRV of the output node OUT is formed at a high level. As the driving signal DRV at a high level is generated, the driving switch 110 and the main switch 120 may be turned on (in this case, the third switch SW3 at the output node OUT as the control terminal is also turned on).

There may be a case in which the first input condition transitions to the second input condition independently of the operation of the processor 200. That is, there may be a case in which the processor 200 is applying the enable signal EN at a high level and the disable signal DIS at a low level to the sub-driver 300 according to the first input condition, but noise acts on the enable signal EN so that a state of the enable signal EN transitions to a low level.

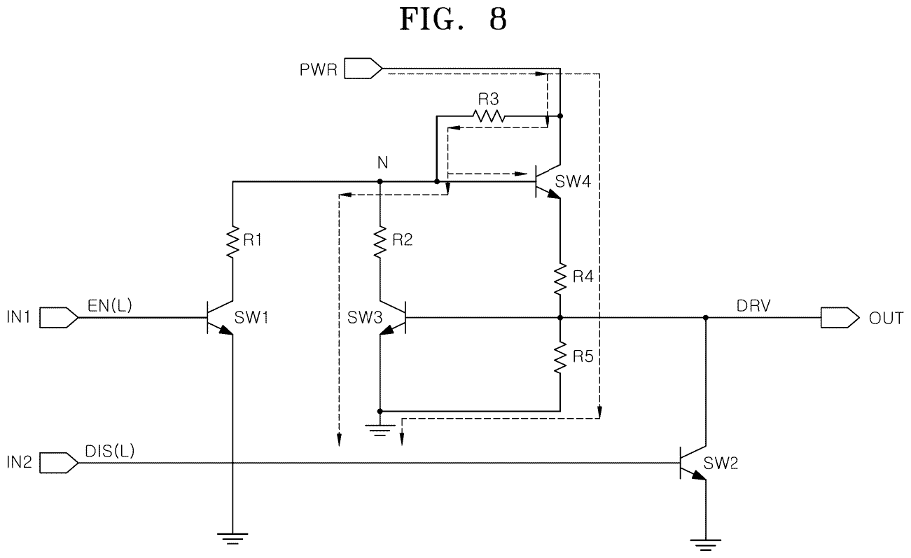

Referring to FIG. 8, when a state of the enable signal EN and a state of the disable signal DIS transition from the first input condition to the second input condition in which the enable signal EN and a state of the disable signal DIS both are at a low level, the first switch SW1 is turned off, and the second switch SW2 remains in a turned-off state.

In this case, since the first switch SW1 is turned off and the third switch SW3 turned on under the first input condition remains in a turned-on state, under the second input condition, a current path along which the power node PWR, the third resistor R3, the second resistor R2, the third switch SW3, and the ground node are connected is formed, and a current flows from the power node PWR to the ground node through the formed current path.

The branch current flowing toward the control terminal of the fourth switch SW4 is maintained due to the herein-described flowing current, and thus the fourth switch SW4 turned on under the first input condition remains in a turned-on state. As the fourth switch SW4 remains in a turned-on state, a constant voltage (power voltage of the second battery B2) is generated at the output node OUT by a current flowing through the fourth switch SW4 and the output resistor R5 connected between the output node OUT and the ground node, and thus a state of the driving signal DRV of the output node OUT is maintained at a high level. As the driving signal DRV at a high level is maintained, a turned-on state of the driving switch 110 and the main switch 120 may be maintained.

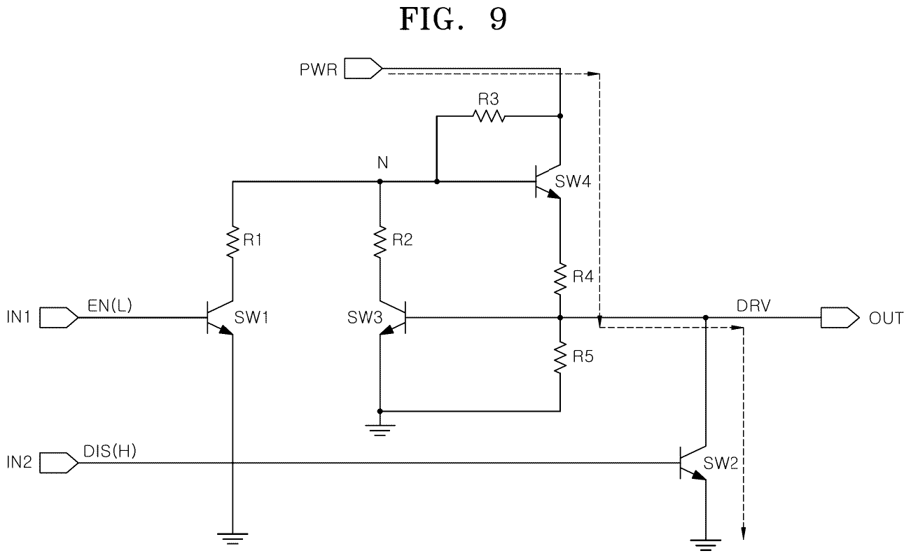

Referring to FIG. 9, when the second input condition transitions to the third input condition in which the enable signal EN at a low level and the disable signal DIS at a low level are input into the first input node IN1 and the second input node IN2 of the sub-driver 300, respectively (which may correspond to a case in which noise acts on the disable signal DIS so that a state of the disable signal DIS transitions from a low level to a high level, or a case in which a state of the disable signal DIS transitions from a low level to a high level under the control of the processor 200, the first switch SW1 remains in a turned-off state, and the second switch SW2 is turned on.

By the turning-on operation of the second switch SW2, a current flowing through the fourth switch SW4 flows to the ground node through the fourth resistor R4 and the second switch SW2.

In addition, by the turning-on operation of the second switch SW2, the output node OUT is connected to the ground node, and a state of the driving signal DRV of the output node OUT is formed at a low level (the third switch SW3 having the output node OUT as the control terminal is also turned off). As the driving signal DRV at a low level is generated at the output node OUT, the driving switch 110 and the main switch 120 may be turned off.

There may be a case in which the third input condition transitions to the fourth input condition independently of the operation of the processor 200. That is, there may be a case in which the processor 200 is applying the enable signal EN at a low level and the disable signal DIS at a high level to the sub-driver 300 according to the third input condition, but noise acts on the enable signal EN so that a state of the enable signal EN transitions to a high level.

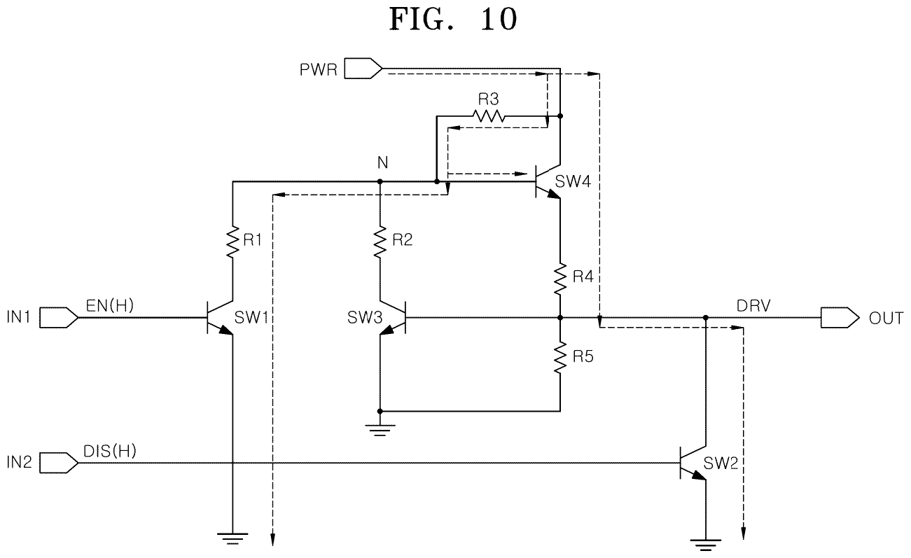

Referring to FIG. 10, when a state of the enable signal EN and a state of the disable signal DIS transition from the third input condition to the fourth input condition in which the enable signal EN and the disable signal DIS both are at a high level, the first switch SW1 is turned on, and the second switch SW2 remains in a turned-on state.

As the first switch SW1 is turned on, a current path along which the power node PWR, the third resistor R3, the first resistor R1, the first switch SW1, and the ground node are connected is formed, but a current flowing through the current path formed in this manner does not affect a level of the driving signal DRV of the output node OUT connected to the ground node due to the turning-on of the second switch SW2. A current flowing through the fourth switch SW4 flows to the ground node through the fourth resistor R4 and the second switch SW2.

That is, as a turned-on state of the second switch SW2 is maintained, the output node OUT is connected to the ground node, and a state of the driving signal DRV of the output node OUT is maintained at a low level (the third switch SW3 having the output node OUT as the control terminal also remains in a turned-off state). As the driving signal DRV at a low level at the output node OUT is maintained, the driving switch 110 and the main switch 120 may remain in a turned-off state.

As described herein, when the first input condition transitions to the second input condition (that is, in a state in which the processor 200 is applying the enable signal EN at a high level and the disable signal DIS at a low level to the sub-driver 300 according to the first input condition, when noise acts on the enable signal EN so that a state of the enable signal EN transitions to a low level), the driving signal DRV at a high level, which is generated at the output node OUT under the first input condition, is maintained even in a state in which the first input condition transitions to the second input condition. This means that the main switch 120 may be controlled to be turned on under the control of the processor 200 irrespective of whether noise acts on the enable signal EN.

In addition, when the third input condition transitions to the fourth input condition (that is, in a state in which the processor 200 is applying the enable signal EN at a low level and the disable signal DIS at a low level to the sub-driver 300 according to the third input condition, when noise acts on the enable signal EN so that a state of the enable signal EN transitions to a high level), the driving signal DRV at a low level, which is generated at the output node OUT under the third input condition, is maintained even in a state in which the third input condition transitions to the fourth input condition. This means that the main switch 120 may be controlled to be turned off under the control of the processor 200 irrespective of whether noise acts on the enable signal EN.

Furthermore, when a state of the enable signal EN and a state of the disable signal DIS are both formed at a high level according to the fourth input condition (that is, when the enable signal EN and the disable signal DIS are at a mutually incompatible state), the sub-driver 300 is configured to drive the driving switch 110 by prioritizing the disable signal DIS, and thus a voltage (high voltage) of the first battery B1 is supplied to the load L, thereby preventing an accident caused by the unintended operation of the load L.

As such, according to the present disclosure, by adopting a signal duplication topology in which a disable signal for an operation of turning a main switch off is added as a control signal of the main switch in addition to an enable signal for an operation of turning the main switch on, and a driver duplication topology in which a sub-driver operating as a latch circuit that maintains an operating state of a main driver for driving the main switch is added, it is possible to prevent an unintended malfunction of the main switch and improve the operation reliability and operation stability of the main switch.

However, effects that can be achieved through the present disclosure are not limited to the herein-described effects and other effects that are not described may be clearly understood by those skilled in the art from the detailed descriptions.

Implementations described herein may be implemented in, for example, a method or process, an apparatus, a software program, a data stream, or a signal. Although discussed only in the context of a single form of implementation (e.g., discussed only as a method), implementations of the discussed features may also be implemented in other forms (for example, an apparatus or a program). The apparatus may be implemented in suitable hardware, software, firmware, and the like. A method may be implemented in an apparatus such as a processor, which is generally a computer, a microprocessor, an IC, a processing device including a programmable logic device, or the like. Processors also include communication devices such as a computer, a cell phone, a portable/personal digital assistant (“PDA”), and other devices that facilitate communication of information between end-users.

Although the present disclosure has been described with reference to embodiments and drawings illustrating aspects thereof, the present disclosure is not limited thereto. Various modifications and variations can be made by a person skilled in the art to which the present disclosure belongs within the scope of the technical spirit of the present disclosure and the claims and their equivalents, herein.

What is claimed is:

1. A switch driver for driving a control target switch, the switch driver comprising:
a first switch turned on or off according to a state of an enable signal input through a first input node to perform an operation of turning on the control target switch;
a second switch turned on or off according to a state of a disable signal input through a second input node to perform an operation of turning off the control target switch and connected an output node at which a driving signal for driving turning-on or turning-off of the control target switch is generated;
a third switch turned on or off in a complementary manner to the second switch; and
a fourth switch connected between the output node and a power node to which a power voltage for generating the driving signal is input and configured to drive a flow of a current for generating the driving signal,
wherein the first to fourth switches operate as a latch circuit configured to maintain a current state of the driving signal when a predefined latch condition is satisfied according to the state of the enable signal and the state of the disable signal.

2. The switch driver of claim 1, wherein the latch condition is a condition in which the state of the enable signal transitions while the disable signal remains in a same state.

3. The switch driver of claim 1, further comprising a connection circuit configured to connect the first to fourth switches to operate the first to fourth switches as the latch circuit when the latch condition is satisfied.

4. The switch driver of claim 3, wherein each of the first to fourth switches is implemented as a transistor including a control terminal to which a control signal for determining turning-on or turning-off of each switch is input, and a current supply terminal and a current discharge terminal which are electrically connected to one another and allow a current to flow when each switch is turned on.

5. The switch driver of claim 4, wherein the current supply terminal of the first switch, the current supply terminal of the third switch, the control terminal of the fourth switch, and the power node are connected in common through the connection circuit.

6. The switch driver of claim 5, wherein the current supply terminal of the second switch, the control terminal of the third switch, and the current discharge terminal of the fourth switch are connected to the output node through the connection circuit, and
the current discharge terminal of the second switch is connected to a ground node.

7. The switch driver of claim 6, wherein the connection circuit includes an output resistor connected between the output node and the ground node to form the state of the driving signal to be at a high level.

8. The switch driver of claim 7, wherein, under a first input condition in which the state of the enable signal and the state of the disable signal are at a high level and a low level, respectively,
the fourth switch is turned on by a branch current branching off from a current generated when the first switch is turned on, and
the state of the driving signal is formed at a high level by the output resistor and a current flowing through the fourth switch as the fourth switch is turned on.

9. The switch driver of claim 8, wherein, when the first input condition transitions to a second state in which the state of the enable signal is at a low level, as a turned-on state of the fourth switch is maintained, the state of the driving signal is maintained at a high level by the output resistor and the current flowing through the fourth switch.

10. The switch driver of claim 9, wherein the first input condition transitions to the second input condition independently of an operation of a processor configured to apply the enable signal and the disable signal to the first and second switches, respectively.

11. The switch driver of claim 7, wherein, under a third input condition in which the state of the enable signal and the state of the disable signal are at a low level and a high level, respectively, as the second switch is turned on and the output node is connected to the ground node, the state of the driving signal is formed at a low level.

12. The switch driver of claim 11, wherein, when the third input condition transitions to a fourth input condition in which the state of the enable signal is at a high level, as a turned-on state of the second switch is maintained, the state of the driving signal is maintained at a low level.

13. The switch driver of claim 12, wherein the third input condition transitions to the fourth input condition independently of an operation of a processor configured to apply the enable signal and the disable signal to the first and second switches, respectively.

14. The switch driver of claim 1, wherein the control target switch includes a high-side switch (HSS) or a low-side switch (LSS) which is turned on or off by the driving signal to drive the main switch.

15. A battery management system comprising:
a main switch configured to allow or block power supply to a load;
a main driver including a driving switch configured to drive the main switch;
a sub-driver configured to apply a driving signal to the main driver through a plurality of switches to drive the driving switch of the main driver; and
a processor configured to control an operation of the sub-driver by respectively applying an enable signal and a disable signal to a first switch and a second switch among the plurality of switches included in the sub-driver, wherein the enable signal is a signal for an operation of turning on the driving switch, and the disable signal is a signal for an operation of turning off the driving switch,
wherein the sub-driver operates as a latch circuit configured to maintain a current state of the driving signal when a predefined latch condition is satisfied according to a state of the enable signal and a state of the disable signal.

16. The battery management system of claim 15, wherein the sub-driver includes:
a first switch turned on or off according to the state of the enable signal;
a second switch turned on or off according to the state of the disable signal and connected to an output node at which the driving signal is generated;
a third switch turned on or off in a complementary manner to the second switch; and
a fourth switch connected between the output node and a power node to which a power voltage for generating the driving signal is input and configured to drive a flow of a current for generating the driving signal,

17. The battery management system of claim 16, wherein the latch condition is a condition in which the state of the enable signal transitions while the disable signal remains in a same state.

18. The battery management system of claim 15, wherein the main switch includes a relay including a relay coil and a contact switch configured to perform a contact switching operation according to whether the relay coil is electrically connected, and
the driving switch includes a high-side switch (HSS) or a low-side switch (LSS) which controls whether to electrically connect the relay coil.

19. A battery pack comprising:
a main switch configured to allow or block an electrical connection between a first battery and a load;
a main driver including a driving switch configured to drive the main switch by being turned on or off according to whether an electrical connection is made with the second battery;
a sub-driver configured to apply a driving signal to the main driver through a plurality of switches to drive the driving switch of the main driver; and
a processor configured to control an operation of the sub-driver by respectively applying an enable signal and a disable signal to a first switch and a second switch among the plurality of switches included in the sub-driver, wherein the enable signal is a signal for an operation of turning on the driving switch, and the disable signal is a signal for an operation of turning off the driving switch,
wherein the sub-driver is configured to drive the driving switch by prioritizing the disable signal when the enable signal and the disable signal are at a mutually incompatible state.

20. The battery pack of claim 19, wherein, when the state of the enable signal and the state of the disable signal both are at a high level, the sub-driver is configured to form the state of the driving signal to be at a low level and apply the driving signal to the main driver, and
when the state of the driving signal is formed at a low level, the driving switch and the main switch provide a turning-off operation to cut off the electrical connection between the first battery and the load.
